(19) United States
(12) Patent Application Publication
(10) Pub. No.: US 2024/0086653 A1
(43) Pub. Date: Mar. 14, 2024

(54) MEMORY CARD SOCKET

(71) Applicant: Kioxia Corporation, Tokyo (JP)

(72) Inventor: Akihiro IIDA, Kamakura Kanagawa (JP)

(73) Assignee: Kioxia Corporation, Tokyo (JP)

(21) Appl. No.: 18/178,209

(22) Filed: Mar. 3, 2023

(30) Foreign Application Priority Data
Sep. 9, 2022 (JP) 2022-144097

(51) Int. Cl. G06K 7/00; H05K 7/20

(52) U.S. Cl. CPC G06K 7/0082; G06K 7/003; H05K 7/20436

(57) ABSTRACT

A memory card socket includes a first pad provided in a first face of a first substrate; a first terminal having a first end portion that contacts a terminal of a memory card and a second end portion electrically connected to the first pad; a holder provided on the first face and fixing the first terminal to the first substrate; and a protrusion provided on the first face, having a second face that contacts a portion of the memory card that excludes the terminal, and including a metal material or an insulating material.

### CROSS-REFERENCE TO RELATED APPLICATION(S)

This application is based upon and claims the benefit of priority from Japanese Patent Application No. 2022-144097, filed Sep. 9, 2022, the entire contents of which are incorporated herein by reference.

### FIELD

Embodiments described herein relate generally to a memory card socket.

### BACKGROUND

A memory card socket for mounting a memory card in an electronic device is known.

### DESCRIPTION OF THE DRAWINGS

FIG. 1A is a plan view illustrating an example of configurations of a memory card socket according to a first embodiment.

FIG. 1B is a cross-sectional view illustrating an example of configurations of the memory card socket according to the first embodiment.

FIG. 1C is a cross-sectional view illustrating an example of configurations of the memory card socket according to the first embodiment when a memory card is inserted.

FIG. 2 is a cross-sectional view illustrating an example of configurations of a memory card socket according to a second embodiment.

FIG. 3A is a plan view illustrating an example of configurations of a memory card socket according to a third embodiment.

FIG. 3B is a cross-sectional view illustrating the example of configurations of the memory card socket according to the third embodiment.

FIG. 4A is a plan view illustrating an example of configurations of a memory card socket according to a fourth embodiment.

FIG. 4B is a cross-sectional view illustrating an example of configurations of the memory card socket according to the fourth embodiment.

### DETAILED DESCRIPTION

Embodiments provide a memory card socket capable of efficiently dissipating heat from a memory card.

In general, according to one embodiment, a memory card socket includes a first pad provided in a first face of a first substrate; a first terminal having a first end portion that contacts a terminal of a memory card and a second end portion electrically connected to the first pad; a holder provided on the first face and fixing the first terminal to the first substrate; and a protrusion provided on the first face, having a second face that contacts a portion of the memory card that excludes the terminal, and including a metal material or an insulating material.

Hereinafter, embodiments according to the disclosure will be described with reference to the drawings. The present embodiments are not intended to limit the disclosure. The drawings are schematic or conceptual, and a proportion and the like of each portion are not necessarily the same as actual ones. In the description and the drawings, elements similar to those previously described with reference to a preceding figure are denoted by the same reference signs, and the detailed descriptions thereof will be appropriately omitted.

### First Embodiment

(Configurations of Memory Card Socket 100)

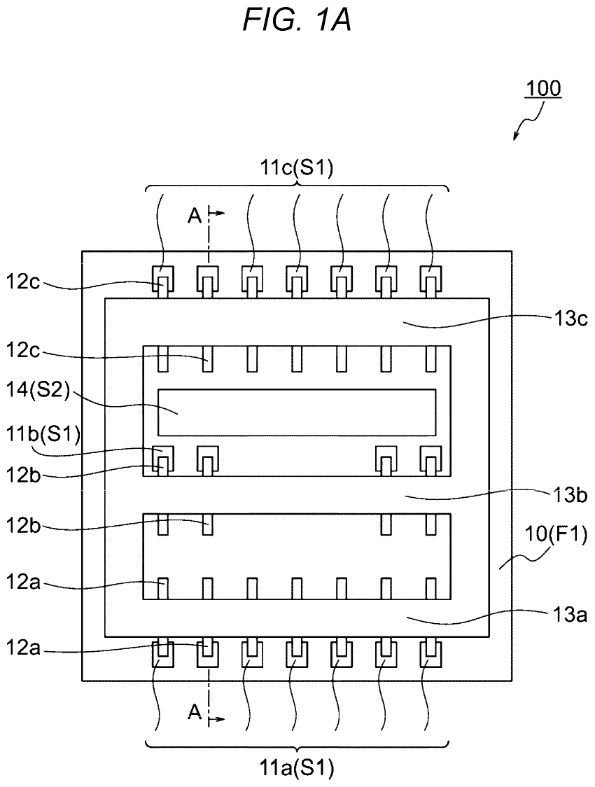

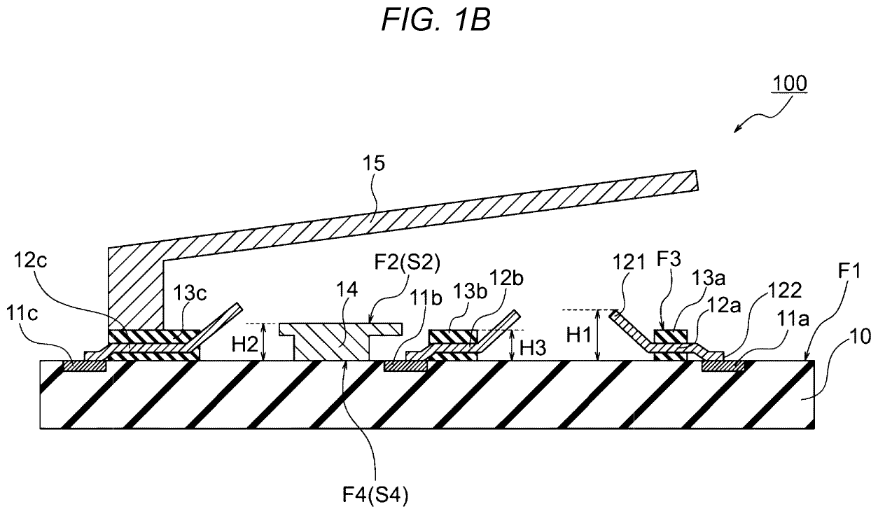

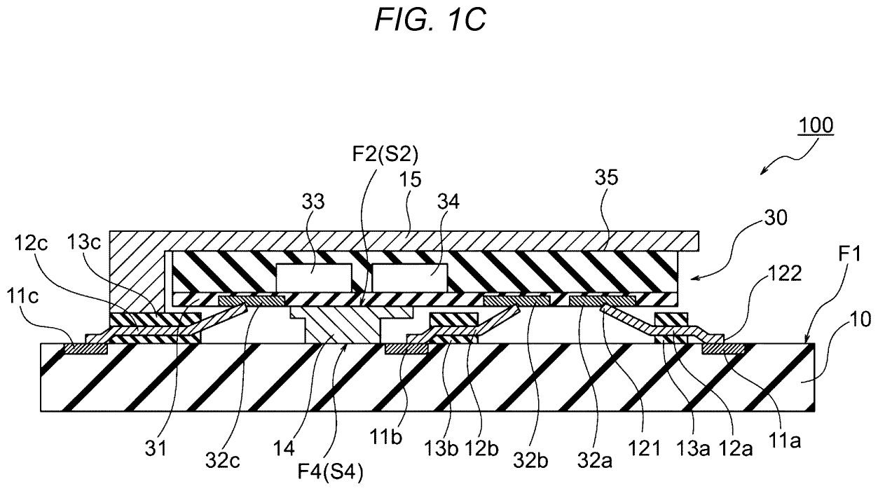

Configurations of a memory card socket 100 according to a first embodiment will be described with reference to FIG. 1A to 1C.

FIG. 1A is a plan view illustrating an example of the configurations of the memory card socket 100 according to the first embodiment. A lid 15 is not illustrated in FIG. 1A. FIGS. 1B and 1C are cross-sectional views illustrating an example of configurations of the memory card socket 100 according to the first embodiment. FIGS. 1B and 1C are cross-sectional views of the memory card socket 100 taken along line AA of FIG. 1A. FIG. 1B illustrates a state in which a memory card 30 is not inserted into the memory card socket 100. FIG. 1C illustrates a state in which the memory card 30 is inserted into the memory card socket 100.

As illustrated in FIGS. 1A to 1C, the memory card socket 100 includes metal terminals 12a to 12c, holders 13a to 13c, a protrusion 14, and the lid 15.

The memory card socket 100 is mounted in an electronic device such as a personal computer, a smartphone, or a tablet terminal. The memory card socket 100 is mounted on a substrate 10 of the electronic device. The memory card socket 100 is a socket configured so that the memory card 30 can be inserted into and extracted from the socket.

The substrate 10 is an example of a first substrate. The substrate 10 has a face, i.e., first face, F1. An insulating material such as glass epoxy resin is used for the substrate 10. A plurality of interconnection layers, a plurality of through vias, and the like formed from a metal material are provided in the substrate 10.

As illustrated in FIG. 1B, the metal pads 11a to 11c, the metal terminals 12a to 12c, the holders 13a to 13c, the protrusion 14, and the lid 15 are provided on or in the face F1 of the substrate 10. The metal pads 11a to 11c, which are identical in configurations, are also referred to simply as “metal pads 11” hereinafter. The metal terminals 12a to 12c, which are identical in configurations, are also referred to simply as “metal terminals 12” hereinafter. The holders 13a to 13c, which are identical in configurations, are also referred to simply as “holders 13” hereinafter.

Each metal pad 11 is buried in a surface of the face F1, as illustrated in FIG. 1B. The metal pad 11 is an example of a first pad. A surface of the metal pad 11 is exposed on the face F1. The metal pad 11 is electrically connected to one end of one metal terminal 12. For example, a conductive material such as copper or gold is used for the metal pad 11. As illustrated in FIG. 1A, the metal pad 11 has a surface area of an area S1, and the number of provided metal pads 11 is freely selected.

As illustrated in FIG. 1B, each metal terminal 12 has a first end portion 121 and a second end portion 122. The metal terminal 12 is an example of a first terminal. A conductive material such as copper or gold is used for the metal terminals 12. Of the metal terminal 12, the first end portion 121 is electrically connected to a metal pad 32, to be described later, of the memory card 30, and the second end portion 122 is electrically connected to the metal pad 11. A vertical distance from the first end portion 121 to the face F1 is a distance H1. The distance H1 is an example of a first distance. It is noted that one metal terminal 12 may be provided to correspond to one metal pad 11.

As illustrated in FIG. 1B, each holder 13 is provided on the face F1. A resin material such as liquid crystal polymer, i.e., LCD, is used for the holder 13. The holder 13 fixes the metal terminals 12 to the substrate 10 to cover portions of the metal terminals 12 between the first end portions 121 and the second end portions 122 from outside. Since the insulating material such as LCP is used for the holder 13, the holder 13 is electrically separated from the metal terminals 12. A vertical distance from a face, i.e., third face, F3 of the holder 13 to the face F1 is a distance H3. The distance H3 is an example of a third distance. The face F3 is a face of the holder 13 opposed to the memory card 30 when the memory card 30 is inserted into the memory card socket 100.

As illustrated in FIG. 1B, the protrusion 14 is provided on the face F1. For example, a high thermal conductivity metal material such as gold or a high thermal conductivity insulating material such as resin is used for the protrusion 14. When the conductive metal material is used for the protrusion 14, the protrusion 14 is apart from and electrically separated from the metal pads 11 and the metal terminals 12. When the insulating material is used for the protrusion 14, the protrusion 14 may not necessarily be apart from the metal pads 11, the metal terminals 12, and the holders 13. The protrusion 14 has a face, i.e., fourth face, F4 that contacts the face F1 and a face, i.e., second face, F2 opposite to the face F4. The face F2 has a surface area of an area S2 and the face F4 has a surface area of an area S4. A vertical distance from the face F2 to the face F1 is a distance H2. The distance H2 is an example of a second distance.

As illustrated in FIG. 1C, when the memory card 30 is inserted into the memory card socket 100, the lid 15 presses the memory card 30 toward the substrate 10. The first end portion 121 of each metal terminal 12 is thereby pressed against one metal pad 32 of the memory card 30 and stably and electrically connected to the metal pad 32. The lid of the memory card socket 100 also can hold the memory card 30. Stainless steel or the like is used for the lid 15. When holding the memory card 30, the lid 15 may contact an upper surface of an encapsulation resin 35 of the memory card 30 to be described later. The lid 15 can thereby dissipate heat generated in the memory card 30. While the lid 15 is formed on the holder 13c, a location of the lid 15 is not limited to this one. For example, the lid 15 may be formed on the holder 13a or not on the holders 13 but on the substrate 10.

Although not illustrated, a sensor sensing insertion of the memory card 30 into the memory card socket 100 may be provided.

(Configurations of Memory Card 30)

As illustrated in FIG. 1C, the memory card 30 includes a circuit board 31, metal pads 32a to 32c, a circuit section 33, a memory section 34, and the encapsulation resin 35.

The circuit board 31 has a circuit pattern and the like, and various configurations of the memory card 30 are provided on the circuit board 31. An insulating material such as glass epoxy resin is used for the circuit board 31. The metal pads 32a to 32c are provided on a face, which is closer to the substrate 10, of the circuit board 31. The metal pads 32a to 32c, which are identical in configurations, are also referred to simply as “metal pads 32” hereinafter.

Each metal pad 32 is provided on the face, which is closer to the substrate 10, of the circuit board 31. When the memory card 30 is inserted into the memory card socket 100, the metal pad 32 is pressured toward the first end portion 121 of one metal terminal 12 and electrically connected to the metal terminal 12. For example, a conductive material such as gold (Au) is used for the metal pad 32. It is noted that one metal pad 32 may be connected and correspond to one metal terminal 12.

The circuit section 33 is provided on the circuit board 31. The circuit section 33 is a control circuit that controls the various configurations of the memory card 30. For example, the circuit section 33 transmits control signals to the memory section 34 to control writing of data to the memory section 34, reading of data from the memory section 34, erasure of data from the memory section 34, and the like, and manages a data storage state of the memory section 34. The circuit section 33 may be a freely selected logic circuit.

The memory section 34 is provided on the circuit board 31. The memory section 34 stores and manages data received from the outside of the memory card 30. The data is stored in memory cells or the like, not illustrated, of the memory section 34, and data read and the like are performed through a cell current carried in the memory cells. The memory section 34 may be a freely selected memory chip such as a NAND flash memory.

The circuit section 33 and the memory section 34 are electrically connected to the metal pads 32 via metal interconnections and the like, not illustrated in detail, in the circuit board 31. In addition, each metal pad 11 and each metal terminal 12 of the memory card socket 100 are electrically connected to each other. The circuit section 33 and the memory section 34 are thereby electrically connected to the metal pad 11. Furthermore, the metal pad 11 is electrically connected to configurations of the electronic device. In this way, the memory card 30 is electrically connected to the electronic device, and data can be exchanged between the memory card 30 and the electronic device.

The encapsulation resin 35 is provided on a face, which is closer to the lid 15, of the circuit board 31, encapsulates and protects the circuit section 33 and the memory section 34. An insulating material such as epoxy resin is used for the encapsulation resin 35. Using the insulating material for the encapsulation resin 35 can ensure that the lid 15 is electrically separated from the circuit section 33 and the memory section 34 even when the lid 15 contacts the encapsulation resin 35 as described above.

The memory card 30 may be a solid state drive, i.e., SSD.

(Heat Dissipation from Memory Card 30 by Protrusion 14)

How to dissipate heat generated from the memory card 30 by the protrusion 14 will now be described in detail with reference to FIGS. 1A to 1C.

The memory card 30 operates at a higher speed than SSDs and, therefore, processes more data per unit time. Owing to this, the circuit section 33 transmits more control signals per unit time, and a higher cell current flows in the memory section 34 per unit time. The circuit section 33 and the memory section 34, therefore, have relatively high calorific values and the memory card 30 has a higher calorific value than the SSDs. The heat generated from the memory card 30 is dissipated to the electronic device through contact surfaces between the metal terminals 12 of the memory card socket 100 and the metal pads 32 of the memory card 30. However, contact areas between the metal terminals 12 of the memory card socket 100 and the metal pads 32 of the memory card 30 are relatively small. Therefore, when the memory card 30 has a high calorific value, the memory card 30 becomes hot. In light of these circumstances, according to the present embodiment, the protrusion 14 is provided in the memory card socket 100 to dissipate the heat from the memory card 30 more efficiently.

As illustrated in FIG. 1C, the face F2 of the protrusion 14 contacts the circuit board 31 of the memory card 30 and the face F4 thereof contacts the substrate 10. As described above, the high thermal conductivity material is used for the protrusion 14. Therefore, the heat generated from the memory card 30 is dissipated toward the electronic device via the protrusion 14. That is, the protrusion 14 functions as a heat sink of the memory card 30. Therefore, heat dissipation by the protrusion 14 can prevent the metal terminals 12 and the metal pads 32 from becoming hot.

As illustrated in FIG. 1A, the protrusion 14 has the area S2, which is sufficiently larger than the area S1 of the metal pad 11. Therefore, the heat can be dissipated from a contact surface between the protrusion 14 and the circuit board 31 more efficiently than the contact surfaces between the metal terminals 12 and the metal pads 32. A portion of the circuit board 31 contacted by the protrusion 14 is desirably immediately under the circuit section 33 or the memory section 34. The reason is as follows. The portions where the heat is generated are mainly the circuit section 33 and the memory section 34 of the memory card 30, as described above. Therefore, the protrusion 14 serving as the heat sink can dissipate the heat more efficiently when being located near the circuit section 33 or the memory section 34.

Furthermore, as illustrated in FIG. 1C, the protrusion 14 may have a T-shaped cross-section with the area S2 of the face F2 larger than the area S4 of the face F4. With the relatively wide face F2, the contact surface between the protrusion 14 and the memory card 30 is also relatively wide. The protrusion 14 can thereby dissipate the heat generated from the memory card 30 more efficiently.

As illustrated in FIG. 1B, when the memory card 30 is not inserted into the memory card socket 100, the height, i.e., distance H2, of the protrusion 14 is smaller than the height, i.e., distance H1, of the first end portion 121 of each metal terminal 12 and larger than the height, i.e., distance H3, of each holder 13. In other words, when the memory card 30 is not inserted into the memory card socket 100, the distance H1 from the face F1 of the substrate 10 to the first end portion 121 of the metal terminal 12 is longer than the distance H2 from the face F1 to the face F2. In addition, when the memory card 30 is not inserted into the memory card socket 100, the distance H3 from the face F1 to an upper surface of the holder 13 is shorter than the distances H1 and H2.

In the present embodiment, the protrusion 14 needs to contact the memory card 30 as the heat sink and the metal terminals 12 need to contact, i.e., to be electrically connected to the metal pads 32 for data exchange.

If the height of the protrusion 14 is larger than the height of the first end portion 121, the first end portion 121 cannot contact each metal pad 32 of the memory card 30 even with the memory card 30 inserted into the memory card socket 100. This is why the height of the protrusion 14 needs to be smaller than the height of the first end portion 121. As illustrated in FIG. 1C, when the memory card 30 is inserted into the memory card socket 100 and the lid 15 is closed, the memory card 30 presses down each metal terminal 12. The metal terminal 12 is slightly elastic. Therefore, when being pressed down by the memory card 30, the first end portion 121 bends down to the height as same as the height, i.e., distance H2, of the protrusion 14. Therefore, even when the height of the protrusion 14 is smaller than the height of the first end portion 121 of the metal terminal 12, the memory card 30 can contact the protrusion 14.

On the other hand, when the height of the protrusion 14 is smaller than the height of each holder 13, the protrusion 14 cannot contact the memory card 30. The holder 13 is not elastic, unlike the metal terminal 12. Therefore, the height, i.e., distance H3, of the holder 13 hardly changes no matter how the memory card 30 presses down the holder 13. Therefore, the height of the protrusion 14 needs to be larger than the height of the holders 13 for the protrusion 14 to contact the memory card 30.

The memory card socket 100 can thereby realize both the heat dissipation from the memory card 30 by the protrusion 14 and the data exchange by electrical connection between the metal terminals 12 and the metal pads 32.

As described so far, according to the first embodiment, the protrusion 14 functions as the heat sink that contacts the memory card 30 when the memory card 30 is inserted into the memory card socket 100 and dissipates the heat generated from the memory card 30 toward the electronic device. This can prevent the metal terminals 12 and the metal pads 32 from becoming hot.

According to the first embodiment, the height of the protrusion 14 is smaller than the height of the first end portion 121 and larger than the height of the holder 13. That is, when the memory card 30 is not inserted into the memory card socket 100, the distance H1 from the face F1 of the substrate 10 to the first end portion 121 of the metal terminal 12 is longer than the distance H2 from the face F1 to the face F2. In addition, when the memory card 30 is not inserted into the memory card socket 100, the distance H3 from the face F1 to an upper surface of the holder 13 is shorter than the distances H1 and H2. This enables the protrusion 14 to contact the circuit board 31 and the first end portion 121 to be electrically connected to each metal pad 32 when the memory card 30 is inserted into the memory card socket 100. Therefore, the memory card socket 100 can realize both the heat dissipation from the memory card 30 by the protrusion 14 and the data exchange by the electrical connection between the metal terminals 12 and the metal pads 32.

Furthermore, the heat dissipation face, i.e., face F2, of the protrusion 14 may be wider than the mounting surface, i.e., face F4. With the relatively wide heat dissipation face, the contact surface between the protrusion 14 and the memory card 30 is relatively wide. The heat generated from the memory card 30 can be, therefore, dissipated more efficiently.

### Second Embodiment

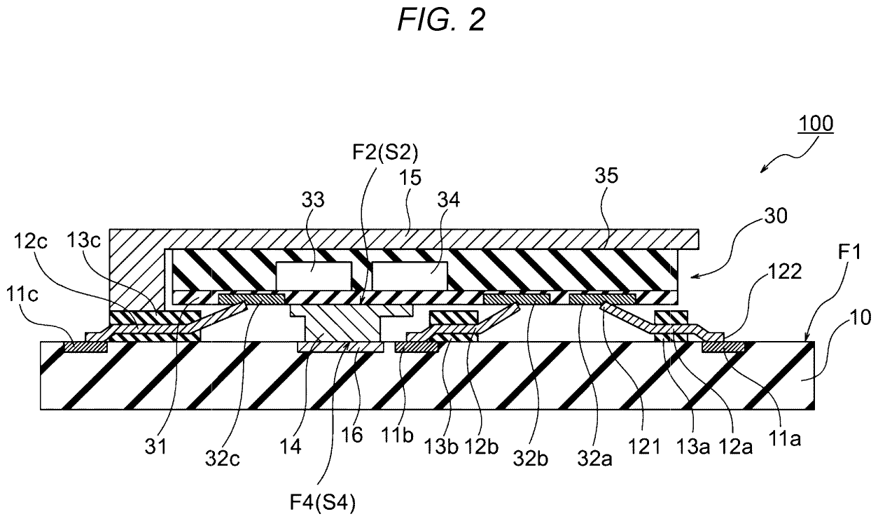

FIG. 2 is a plan view illustrating an example of configurations of the memory card socket 100 according to a second embodiment. The second embodiment differs from the first embodiment in that the memory card socket 100 includes a metal layer 16 between the substrate 10 and the protrusion 14.

The metal layer 16 is buried in the substrate 10 under the face F4 of the protrusion 14. A relatively high thermal conductivity material, e.g., a metal material such as gold is used for the metal layer 16.

The metal layer 16 is provided to contact the protrusion 14. Therefore, the heat generated from the memory card 30 is also dissipated to the metal layer 16 via the protrusion 14. Owing to this, according to the second embodiment, the heat generated from the memory card 30 is thermally conducted to objects with larger volumes, i.e., the protrusion 14 and the metal layer 16, achieving more efficient heat dissipation. Although not illustrated in detail, the metal layer 16 may be connected further to another heat sink, not illustrated, provided in the substrate 10. In this case, the heat generated from the memory card 30 is thermally conducted to objects with far larger volumes, i.e., the protrusion 14, the metal layer 16, and the heat sink, achieving far more efficient heat dissipation. It is noted that the heat-dissipation heat sink connected to the metal layer 16 is provided not to contact the metal pads 11 and interconnections, not illustrated. This can prevent short-circuit between the heat-dissipation heat sink and the metal pads 11 or the interconnections in the substrate 10. A surface area of the metal layer 16 is preferably larger than the areas of the faces F3 and F4 for enhancing thermal conductivity and heat dissipation.

Other configurations in the second embodiment may be similar to those in the first embodiment. Therefore, the second embodiment can obtain similar effects to those of the first embodiment.

### Third Embodiment

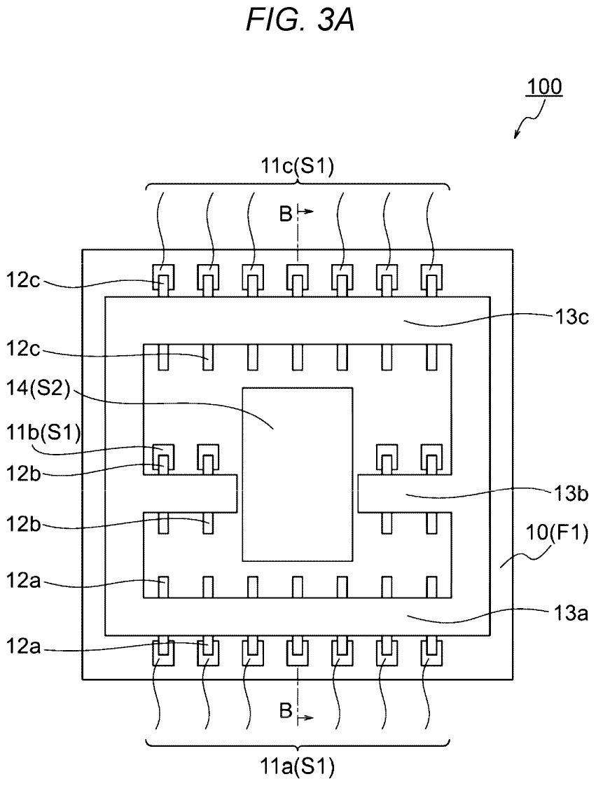

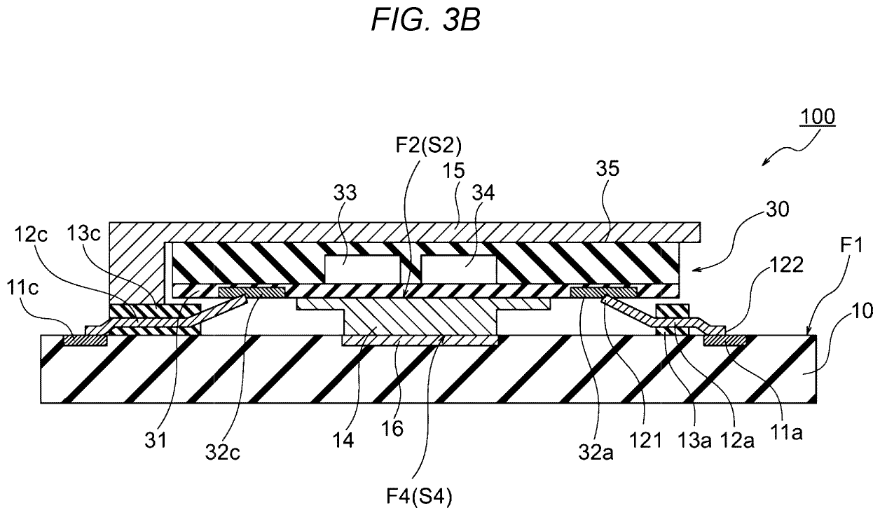

FIG. 3A is a plan view illustrating an example of configurations of the memory card socket 100 according to a third embodiment. FIG. 3B is a cross-sectional view illustrating an example of configurations of the memory card socket 100 according to the third embodiment. FIG. 3B is a cross-sectional view of the memory card socket 100 taken along line BB of FIG. 3A. In the third embodiment, the area of the face F2 of the protrusion 14 is larger than that of the face F2 in the first embodiment.

As illustrated in FIG. 3A, according to the third embodiment, the holder 13b is not provided in portions on the substrate 10 where the metal terminals 12b and the metal pads 11b are not provided. This allows for a wide space in a central portion on the substrate 10. The protrusion 14 is, therefore, provided in this wide space in the central portion. The relatively large protrusion 14 can be thereby provided, making the area S2 of the face F2 of the protrusion 14 relatively large. Therefore, the heat generated from the memory card 30 is conducted via the protrusion 14 having the larger area of the face F2. This enables the heat dissipation from the memory card 30 more efficiently.

For example, as illustrated in FIG. 3B, the protrusion 14 has the face F2 large enough to cover a range immediately under where the circuit section 33 and the memory section 34 are located and can dissipate the heat from the circuit section 33 and the memory section 34 efficiently. While the metal layer 16 is provided under the protrusion 14 in FIG. 3B, the metal layer 16 may not necessarily be provided. The metal layer 16 has similar configurations and effects to those according to the second embodiment.

Other configurations in the third embodiment may be similar to those in the first embodiment. Therefore, the third embodiment can also obtain similar effects to those of the first embodiment.

### Fourth Embodiment

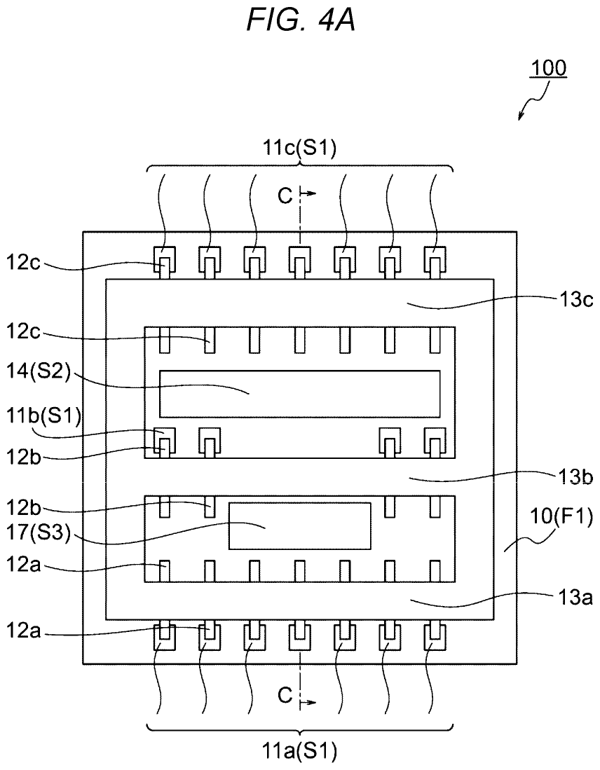

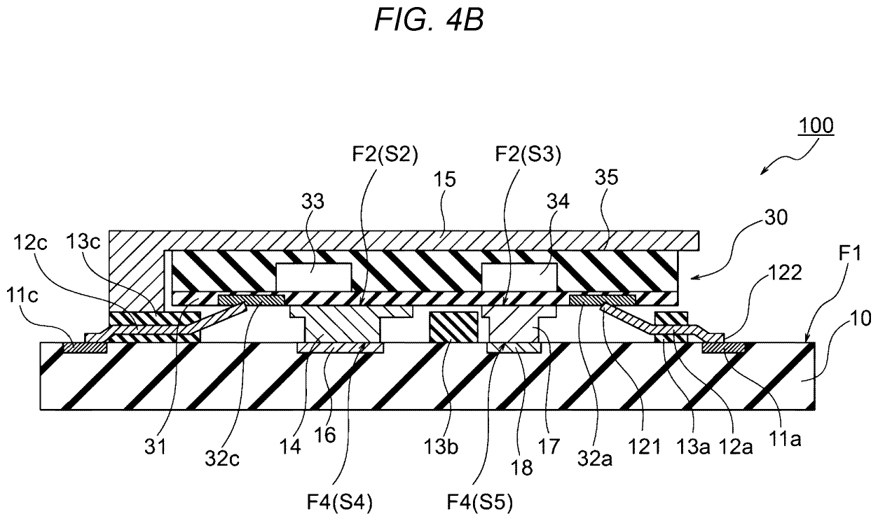

FIG. 4A is a plan view illustrating an example of configurations of the memory card socket 100 according to a fourth embodiment. FIG. 4B is a cross-sectional view illustrating an example of configurations of the memory card socket 100 according to the fourth embodiment. FIG. 4B is a cross-sectional view of the memory card socket 100 taken along line CC of FIG. 4A. The fourth embodiment differs from the first embodiment in that the memory card socket 100 includes a plurality of protrusions 14 and 17. The plurality of protrusions 14 and 17 are disposed not to contact the metal pads 11 and the metal terminals 12.

The protrusion 17 is similar in configurations and functions to the protrusion 14 despite a difference in magnitude. That is, the protrusion 17 is placed on the face F1 of the substrate 10. For example, a high thermal conductivity metal material such as gold or a high thermal conductivity insulating material such as resin is used for the protrusion 17. When the conductive metal material is used for the protrusion 17, the protrusion 17 is apart from and electrically separated from the metal pads 11 and the metal terminals 12. When the insulating material is used for the protrusion 17, the protrusion 17 may not necessarily be apart from the metal pads 11, the metal terminals 12, and the holders 13 and may contact the metal pads 11, the metal terminals 12, and the holders 13.

As illustrated in FIGS. 4A and 4B, the protrusion 17 is provided in a space where the protrusion 14 is not provided and where the metal pads 11, the metal terminals 12, and the holders 13 are not present on the substrate 10. The protrusion 17 is provided in a freely selected region, where the other configurations are not provided, on the substrate 10. A magnitude of an area S3 of the face F2 of the protrusion 17 may be freely selected and may be larger than, smaller than, or equal to the magnitude of the area S2 of the face F2 of the protrusion 14. However, for efficiently dissipating the heat from the memory card 30, the magnitude of the area S3 of the face F2 is desirably larger than an area S5 of the face F4. FIGS. 4A and 4B illustrate one protrusion 17. However, the number of protrusions 17 is not limited to one, and two or more protrusions 17 may be provided from the viewpoints of configurations and layout on the substrate 10. That is, three or more protrusions 17 may be provided.

Providing the protrusion 17 as well as the protrusion 14 enables the face F2 of the protrusion 17 as well as the face F2 of the protrusion 14 to contact the memory card 30. With the configurations, according to the fourth embodiment, the heat generated from the memory card 30 is conducted to both the protrusion 14 and the protrusion 17, achieving more efficient heat dissipation. Furthermore, the protrusion 17 is provided separately from the protrusion 14. As illustrated in FIG. 4B, even when, for example, the circuit section 33 and the memory section 34 are provided apart, then the protrusion 14 can cover a range immediately under where the circuit section 33 is located, and the protrusion 17 can cover a range immediately under where the memory section 34 is located. The protrusions 14 and 17 can thereby efficiently dissipate the heat from the circuit section 33 and the memory section 34. While the metal layer 16 is provided under the protrusion 14 and a metal layer 18 is provided under the protrusion 17 in FIG. 4B, the metal layers 16 and 18 may not necessarily be provided. The metal layers 16 and 18 have similar configurations and effects to those of the metal layer 16 in the second embodiment.

Other configurations in the fourth embodiment may be similar to those in the first embodiment. Therefore, the fourth embodiment can obtain similar effects to those of the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory card socket to which a memory card can be coupled, comprising:
a first terminal having a first end portion that contacts a terminal of a memory card and a second end portion electrically connected to a first pad provided in a first face of a first substrate;
a holder provided on the first face and fixing the first terminal to the first substrate; and
a protrusion provided on the first face, having a second face that contacts a portion of the memory card that excludes the terminal, and including a metal material or an insulating material.

2. A memory card socket to which a memory card can be coupled, comprising:
a first terminal having a first end portion electrically connected to a terminal of the memory card and a second end portion electrically connected to a first pad provided in a first face of a first substrate;
a holder provided on the first face and fixing the first terminal to the first substrate; and
a protrusion provided on the first face, having a second face that contacts a portion of the memory card that excludes the terminal, and configured to dissipate heat from the memory card.

3. The memory card socket according to claim 1, wherein
a first distance from the first face to the first end portion is longer than a second distance from the first face to the second face when the memory card is not coupled to the memory card socket.

4. The memory card socket according to claim 3, wherein
the holder has a third face opposite to the memory card when the memory card is coupled to the memory card socket, and
a third distance from the first face to the third face is shorter than the first distance and the second distance when the memory card is not coupled to the memory card socket.

5. The memory card socket according to claim 1, further comprising:
a metal layer connected to a fourth face of the protrusion opposite to the second face and provided in the first substrate.

6. The memory card socket according to claim 5, wherein
an area of the second face is larger than an area of the fourth face.

7. The memory card socket according to claim 1, comprising:
a plurality of the protrusions, wherein
the plurality of the protrusions are formed of a metal material, and each disposed not to contact the first pad, the first terminal, or the holder.

8. The memory card socket according to claim 1, comprising:
a plurality of the protrusions, wherein
the plurality of the protrusions are formed of an insulating material, and each disposed in a space where the first pad, the first terminal, or the holder is not present.

9. The memory card socket according to claim 1, wherein
an area of the second face is larger than an area of the first pad.

10. The memory card socket according to claim 1, further comprising:
a lid pressing the memory card toward the first substrate when the memory card is coupled to the memory card socket.

11. The memory card socket according to claim 10, wherein
the first substrate is a mounting substrate of an electronic device.

12. The memory card socket according to claim 2, wherein
a first distance from the first face to the first end portion is longer than a second distance from the first face to the second face when the memory card is not coupled to the memory card socket.

13. The memory card socket according to claim 12, wherein
the holder has a third face opposite to the memory card when the memory card is coupled to the memory card socket, and
a third distance from the first face to the third face is shorter than the first distance and the second distance when the memory card is not coupled to the memory card socket.

14. The memory card socket according to claim 2, further comprising:
a metal layer connected to a fourth face of the protrusion opposite to the second face and provided in the first substrate.

15. The memory card socket according to claim 2, comprising:
a plurality of the protrusions, wherein
the plurality of the protrusions are formed of a metal material, and each disposed not to contact the first pad, the first terminal, or the holder.

16. The memory card socket according to claim 2, comprising:
a plurality of the protrusions, wherein
the plurality of the protrusions are formed of an insulating material, and each disposed in a space where the first pad, the first terminal, or the holder is not present.
